(19) United States
(12) Patent Application Publication
(10) Pub. No.: US 2024/0063191 A1
(43) Pub. Date: Feb. 22, 2024

(54) OPTOELECTRONIC DEVICE WITH AXIAL-TYPE THREE-DIMENSIONAL LIGHT-EMITTING DIODES

(71) Applicant: Aledia, Echirolles (FR)

(72) Inventors: Olga Kryliouk, Fort Myers, FL (US); Mehdi Daanoune, Renage (FR); Jérôme Napierala, Saint Egrève (FR)

(73) Assignee: Aledia, Echirolles (FR)

(21) Appl. No.: 18/267,074

(22) PCT Filed: Dec. 2, 2021
(86) PCT No.: PCT/EP2021/083863

§ 371 Date: Jun. 13, 2023

(30) Foreign Application Priority Data
Dec. 17, 2020 (FR) 2013514

(51) Int. Cl. H01L 25/075; H01L 33/08; H01L 33/18; H01L 33/10; H01L 33/00; H01L 33/58

(52) U.S. Cl. CPC H01L 25/0753; H01L 33/08; H01L 33/18; H01L 33/105; H01L 33/0093; H01L 33/58; H01L 2933/0083

(57) ABSTRACT

An optoelectronic device including an array of axial light-emitting diodes, the light-emitting diodes each including an active area configured to emit an electromagnetic radiation having an emission spectrum comprising a maximum at a first wavelength, the array forming a photonic crystal configured to form a resonance peak amplifying the intensity of said electromagnetic radiation at at least one second wavelength different from the first wavelength.

The present patent application claims the priority of the French patent application FR20/13514 which will be considered as forming an integral part of the present description.

### TECHNICAL BACKGROUND

The present disclosure concerns an optoelectronic device, particularly a display screen or an image projection device, comprising light-emitting diodes made up of semiconductor materials, and their manufacturing methods.

### PRIOR ART

A light-emitting diode based on semiconductor materials generally comprises an active area which is the region of the light-emitting diode from which most of the electromagnetic radiation supplied by the light-emitting diode is emitted. The structure and the composition of the active area are adapted to obtain an electromagnetic radiation having the desired properties. In particular, it is generally desired to obtain a narrow-spectrum electromagnetic radiation, ideally substantially monochromatic.

Optoelectronic devices comprising axial-type three-dimensional light-emitting diodes, that is, light-emitting diodes each comprising a three-dimensional semiconductor element extending along a preferred direction and comprising the active area at an axial end of the three-dimensional semiconductor element, are here more particularly considered.

Examples of three-dimensional semiconductor elements are microwires or nanowires comprising a semiconductor material based on a compound mainly comprising at least one group-III element and one group-V element (for example, gallium nitride GaN), called III-V compound hereafter, or mainly comprising at least one group-II element and one group-VI element (for example, zinc oxide ZnO), called II-VI compound hereafter. Such devices are for example described in French patent applications FR 2995729 and FR 2997558.

It is known to form an active area comprising a single quantum well or multiple quantum wells. A single quantum well is formed by interposing, between two layers of a first semiconductor material, for example, a III-V compound, particularly GaN, respectively P- and N-type doped, a layer of a second semiconductor material, for example, an alloy of the IT-V compound and of a third element, particularly, InGaN, having a different bandgap than the first semiconductor material. A multiple quantum well structure comprises a stack of semiconductor layers forming an alternation of quantum wells and of barrier layers.

The wavelength of the electromagnetic radiation emitted by the active area of the optoelectronic device particularly depends on the bandgap of the second material forming the quantum well. When the second material is an alloy of the III-V compound and of a third element, for example, InGaN, the wavelength of the emitted radiation particularly depends on the atomic percentage of the third element, for example, indium. In particular, the higher the atomic percentage of indium, the higher the wavelength.

A disadvantage is that when the atomic percentage of indium exceeds a threshold, differences in lattice parameters can be observed between the GaN and InGaN of the quantum well, which may cause the forming of non-radiative defects in the active layer, such as dislocations and/or alloy separation effects, which causes a significant decrease in the quantum efficiency of the active area of the optoelectronic device. There thus is a maximum wavelength of the radiation emitted by an optoelectronic device having its active area comprising a single quantum well or multiple quantum wells based on III-V or II-VI compounds. In particular, the forming of light-emitting diodes made of III-V or II-VI compounds emitting in red may thus be difficult.

However, the use of materials made from III-V or II-VI compounds is desirable since there exist methods of growing such materials by epitaxy on substrates of large dimensions and at a low cost.

It is known to cover a light-emitting diode with a photoluminescent material capable of converting the electromagnetic radiation emitted by the active area into an electromagnetic radiation at a different wavelength. However, such photoluminescent materials may have a high cost, have a low conversion efficiency, and have a performance which degrades over time.

Further, it may be difficult to form an axial-type three-dimensional light-emitting diode based on III-V or II-VI compounds with an active area having an emission spectrum having the desired properties, in particular comprising a narrow band around the target emission frequency

### SUMMARY

An object of an embodiment aims at overcoming all or part of the disadvantages of the previously-described optoelectronic devices comprising light-emitting diodes.

Another object of an embodiment is for the active area of each light-emitting diode to comprise a stack of semiconductor materials based on III-V or II-VI compounds.

Another object of an embodiment is for the optoelectronic device to comprise light-emitting diodes configured to emit a light radiation in red without using photoluminescent materials.

Another object of an embodiment is that the axial-type three-dimensional light-emitting diodes based on III-V or II-VI compounds with an active area having an emission spectrum having the desired properties, in particular comprising a narrow band around the target emission frequency.

An embodiment provides an optoelectronic device comprising an array of axial light-emitting diodes, the light-emitting diodes each comprising an active area configured to emit an electromagnetic radiation having an emission spectrum comprising a maximum at a first wavelength, the array forming a photonic crystal configured to form a resonance peak amplifying the intensity of said electromagnetic radiation at at least one second wavelength different from the first wavelength.

According to an embodiment, the device further comprises a first optical filter covering at least one first portion of said array of light-emitting diodes, the first optical filter being configured to block said amplified radiation over a first wavelength range comprising the first wavelength and to give way to said amplified radiation over a second wavelength range comprising the second wavelength.

According to an embodiment, the emission spectrum of the active area has energy at the second wavelength.

According to an embodiment, the photonic crystal is configured to form a resonance peak amplifying the intensity of said electromagnetic radiation at at least one third wavelength different from the first and second wavelengths.

According to an embodiment, the emission spectrum of the active area has energy at the third wavelength.

According to an embodiment, the device further comprises a second optical filter covering at least a second portion of said array of light-emitting diodes, the second optical filter being configured to block said amplified radiation over a third wavelength range comprising the first and second wavelengths and to give way to said amplified radiation over a fourth wavelength range comprising the third wavelength.

According to an embodiment, the photonic crystal is configured to form a resonance peak amplifying the intensity of said electromagnetic radiation at at least one fourth wavelength different from the first, second, and third wavelengths.

According to an embodiment, the emission spectrum of the active area has energy at the fourth wavelength.

According to an embodiment, the device further comprises a third optical filter covering at least a third portion of said array of light-emitting diodes, the third optical filter being configured to block said amplified radiation over a fifth wavelength range comprising the first, second, and third wavelengths and to give way to said amplified radiation over a sixth wavelength range comprising the fourth wavelength.

According to an embodiment, the device comprises a support having the light-emitting diodes resting thereon, each light-emitting diode comprising a stack of a first semiconductor portion resting on the support, of the active area in contact with the first semiconductor portion, and of a second semiconductor portion in contact with the active area.

According to an embodiment, the device comprises a reflective layer between the support and the first semiconductor portions of the light-emitting diodes.

According to an embodiment, the reflective layer is made of metal.

According to an embodiment, the second semiconductor portions of the light-emitting diodes are covered with a conductive layer at least partly transparent to the radiation emitted by the light-emitting diodes.

According to an embodiment, the light-emitting diodes are separated by an electrically-insulating material.

An embodiment also provides a method of manufacturing an optoelectronic device comprising an array of axial light-emitting diodes, the light-emitting diodes each comprising an active layer configured to emit an electromagnetic radiation having an emission spectrum comprising a maximum at a first wavelength, the array forming a photonic crystal configured to form a resonance peak amplifying the intensity of the electromagnetic radiation by the electromagnetic diodes at at least one second wavelength different from the first wavelength.

According to an embodiment, the forming of the light-emitting diodes of the array comprises the steps of:
forming second semiconductor portions on a substrate, the first semiconductor portions being separated from one another by the pitch of the array;
forming an active area on each first semiconductor portion; and
forming a first semiconductor portion on each active area.

According to an embodiment, the method comprises a step of removing the substrate.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a partial simplified cross-section view of an embodiment of an optoelectronic device comprising light-emitting diodes;

FIG. 2 is a partial simplified perspective view of the optoelectronic device shown in FIG. 1;

FIG. 3 schematically shows an example of a layout of the light-emitting diodes of the optoelectronic device shown in FIG. 1;

FIG. 4 schematically shows another example of a layout of the light-emitting diodes of the optoelectronic device shown in FIG. 1;

FIG. 5 schematically shows curves of the variation of light intensities of the radiation emitted by the optoelectronic device of FIG. 1 illustrating a configuration with one resonance;

FIG. 6 schematically shows curves of the variation of light intensities illustrating a configuration with two resonances;

FIG. 7 schematically shows curves of the variation of light intensities illustrating a configuration with three resonances;

FIG. 8 illustrates a method of selection of the radiation in a configuration with two resonances;

FIG. 9 illustrates a method of selection of the radiation in a configuration with three resonances;

FIG. 10A illustrates a step of an embodiment of a method of manufacturing the optoelectronic device shown in FIG. 1;

FIG. 10B illustrates another step of the manufacturing method;

FIG. 10C illustrates another step of the manufacturing method;

FIG. 10D illustrates another step of the manufacturing method;

FIG. 10E illustrates another step of the manufacturing method;

FIG. 10F illustrates another step of the manufacturing method;

FIG. 10G illustrates another step of the manufacturing method;

FIG. 11 illustrates a step of another embodiment of a method of manufacturing the optoelectronic device shown in FIG. 1;

FIG. 12 is a grayscale map of the light intensity emitted at a first wavelength by a light-emitting diode of a photonic crystal of the optoelectronic device according to the pitch of the photonic crystal and to the diameter of the light-emitting diode;

FIG. 13 is a grayscale map of the light intensity emitted at a second wavelength by a light-emitting diode of a photonic crystal of the optoelectronic device according to the pitch of the photonic crystal and to the diameter of the light-emitting diode;

FIG. 14 is a grayscale map of the light intensity emitted at a third wavelength by a light-emitting diode of a photonic crystal of the optoelectronic device according to the pitch of the photonic crystal and to the diameter of the light-emitting diode;

FIG. 15 shows a curve of the variation of the light intensity of the light-emitting diodes according to the wavelength measured during a first test; and

FIG. 16 shows a curve of the variation of the light-intensity of the light-emitting diodes according to the wavelength measured during a second test.

### DESCRIPTION OF THE EMBODIMENTS

Like features have been designated by like references in the various figures. In particular, the structural and/or functional features that are common among the various embodiments may have the same references and may dispose identical structural, dimensional and material properties. For the sake of clarity, only the steps and elements that are useful for an understanding of the embodiments described herein have been illustrated and described in detail. In particular, the considered optoelectronic devices optionally comprise other components, which will not be detailed.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., it is referred to the orientation of the drawings or to an optoelectronic device in a normal position of use.

Unless specified otherwise, the expressions “around”, “approximately”, “substantially” and “in the order of” signify within 10%, and preferably within 5%. Further, it is here considered that the terms “insulating” and “conductive” respectively mean “electrically insulating” and “electrically conductive”.

In the following description, the inner transmittance of a layer corresponds to the ratio of the intensity of the radiation coming out of the layer to the intensity of the radiation entering the layer. The absorption of the layer is equal to the difference between 1 and the inner transmittance. In the following description, a layer is said to be transparent to a radiation when the absorption of the radiation through the layer is lower than 60%. In the following description, a layer is said to be absorbing for a radiation when the absorption of the radiation in the layer is higher than 60%. When a radiation has a generally “bell”-shaped spectrum, for example, of Gaussian shape, having a maximum, the expression wavelength of the radiation, or central or main wavelength of the radiation, designates the wavelength at which the maximum of the spectrum is reached. In the following description, the refraction index of a material corresponds to the refraction index of the material for the wavelength range of the radiation emitted by the optoelectronic device. Unless specified otherwise, the refraction index is considered as substantially constant over the wavelength range of the useful radiation, for example, equal to the average of the refraction index over the wavelength range of the radiation emitted by the optoelectronic device.

The term axial light-emitting diode designates a three-dimensional structure having an elongated shape, for example, cylindrical, along a main direction having at least two dimensions, called minor dimensions, in the range from 5 nm to 2.5 μm, preferably from 50 nm to 2.5 μm. The third dimension, called major dimension, is greater than or equal to 1 time, preferably greater than or equal to 5 times, and more preferably greater than or equal to 10 times the largest minor dimension. In certain embodiments, the minor dimensions may be smaller than or equal to approximately 1 μm, preferably in the range from 100 nm to 1 μm, more preferably from 100 nm to 800 nm. In certain embodiments, the height of each light-emitting diode may be greater than or equal to 500 nm, preferably in the range from 1 μm to 50 μm.

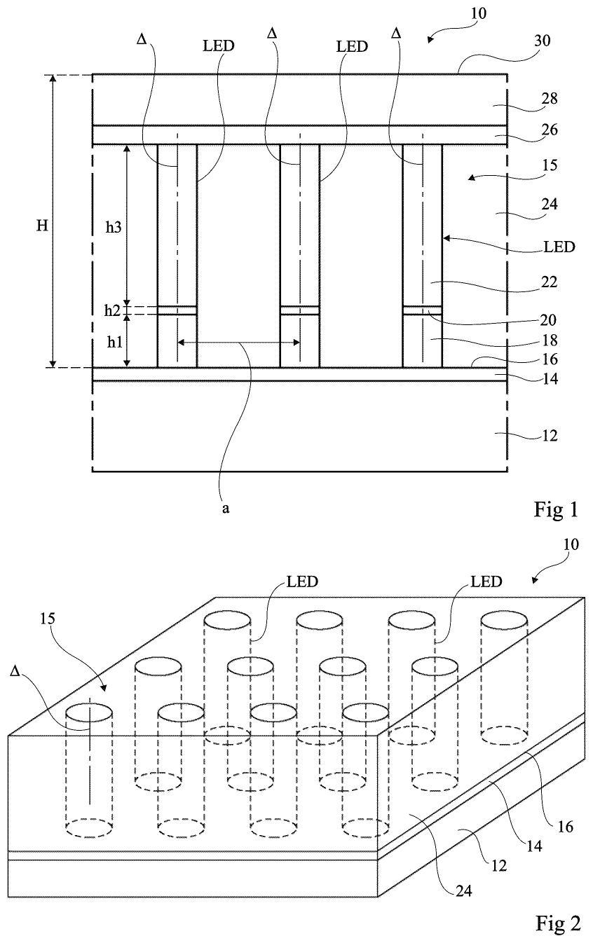

FIGS. 1 and 2 respectively are a lateral cross-section view and a perspective view, partial and simplified, of an embodiment of an optoelectronic device 10 comprising light-emitting diodes.

Optoelectronic device 10 comprises, from bottom to top in FIG. 1:
a support 12;
a first electrode layer 14 resting on support 12 and having an upper surface 16;
an array 15 of axial light-emitting diodes LED resting on surface 16, each axial light-emitting diode comprising, from bottom to top in FIG. 1, a lower semiconductor portion 18, not shown in FIG. 2, in contact with electrode layer 14, an active layer 20, not shown in FIG. 2, in contact with lower semiconductor portion 18, and an upper semiconductor portion 22, not shown in FIG. 2, in contact with active area 20;
an insulating layer 24 extending between light-emitting diodes LED, all along the height of light-emitting diodes LED;
a second electrode layer 26, not shown in FIG. 2, covering the light-emitting diodes LED in contact with the upper semiconductor portions 22 of light-emitting diodes LED; and
a coating 28, not shown in FIG. 2, covering second electrode layer 26, and delimiting an emission surface 30 of optoelectronic device 10.

Each light-emitting diode LED is called axial since active area 20 is in line with lower semiconductor portion 18 and upper semiconductor portion 22 is in line with active area 20, the assembly comprising lower semiconductor portion 18, active area 20, and upper semiconductor portion 22 extending along an axis A, called axis of the axial light-emitting diode. Preferably, the axes A of light-emitting diodes LED are parallel and orthogonal to surface 16.

Support 12 may correspond to an electronic circuit. Electrode layer 14 may be metallic, for example, made of silver, of copper, or of zinc. The thickness of electrode layer 14 is sufficient for electrode layer 14 to form a mirror. As an example, electrode layer 14 has a thickness greater than 100 nm. Electrode layer 14 may totally cover support 12. As a variant, electrode layer 14 may be divided into distinct portions to allow the separate control of groups of light-emitting diodes of the array of light-emitting diodes. According to an embodiment, surface 16 may be reflective. Electrode layer 14 may then have a specular reflection. According to another embodiment, electrode layer 14 may have a lambertian reflection. To obtain a surface having a lambertian reflection, a possibility is to create unevennesses on a conductive surface. As an example, when surface 16 corresponds to the surface of a conductive layer resting on a base, a texturing of the surface of the base may be performed before the deposition of the metal layer so that surface 16 of the metal layer, once deposited, has a relief.

Second electrode layer 26 is conductive and transparent. According to an embodiment, electrode layer 26 is a transparent conductive oxide (TCO) layer, such as indium-tin oxide (ITO), zinc oxide doped or not with aluminum, or with gallium, or graphene. As an example, electrode layer 26 has a thickness in the range from 5 nm to 200 nm, preferably from 20 nm to 50 nm. Insulating layer 24 may be made of an inorganic material, for example, of silicon oxide or of silicon nitride. Insulating layer 24 may be made of an organic material, for example, an insulating polymer based on benzocyclobutene (BCB). Coating 28 may comprise an optical filter, or optical filters arranged next to one another, as will be described in further detail hereafter.

In the embodiment shown in FIGS. 1 and 2, all light-emitting diodes LED have the same height. The thickness of insulating layer 24 is for example selected to be equal to the height of light-emitting diodes LED so that the upper surface of insulating layer 24 is coplanar with the upper surfaces of the light-emitting diodes.

According to an embodiment, lower and upper semiconductor portions 18 and 22 and active areas 20 are at least partly made of a semiconductor material. The semiconductor material is selected from the group comprising III-V compounds, II-VI compounds, and group-IV semiconductors or compounds. Examples of group-III elements comprise gallium (Ga), indium (In), or aluminum (Al). Examples of group-IV elements comprise nitrogen (N), phosphorus (P), or arsenic (As). Examples of III-N compounds are GaN, AlN, InN, InGaN, AlGaN, or AlInGaN. Examples of group-II elements comprise group-IIA elements, particularly beryllium (Be) and magnesium (Mg), and group-JIB elements, particularly zinc (Zn), cadmium (Cd), and mercury (Hg). Examples of group-VI elements comprise group-VIA elements, particularly oxygen (O) and tellurium (Te). Examples of II-VI compounds are ZnO, ZnMgO, CdZnO, CdZnMgO, CdHgTe, CdTe, or HgTe. Generally, the elements in the III-V or II-VI compound may be combined with different molar fractions. Examples of group-IV semiconductor materials are silicon (Si), carbon (C), germanium (Ge), silicon carbide alloys (SiC), silicon-germanium alloys (SiGe), or germanium carbide alloys (GeC). Lower and upper semiconductor portions 18 and 22 may comprise a dopant. As an example, for III-V compounds, the dopant may be selected from the group comprising a P-type group-II dopant, for example, magnesium (Mg), zinc (Zn), cadmium (Cd), or mercury (Hg), a P-type group-IV dopant, for example, carbon (C), or an N-type group-IV dopant, for example, silicon (Si), germanium (Ge), selenium (Se), sulfur (S), terbium (Tb), or tin (Sn). Preferably, lower semiconductor portion 18 is made of P-doped GaN and upper semiconductor portion 22 is made of N-doped GaN.

For each light-emitting diode LED, active area 20 may comprise confinement means. As an example, active area 20 may comprise a single quantum well. It then comprises a semiconductor material different from the semiconductor material forming lower and upper semiconductor layers 18 and 22 and having a bandgap smaller than that of the material forming lower and upper semiconductor layers 18 and 22. Active area 20 may comprise multiple quantum wells. It then comprises a stack of semiconductor layers forming an alternation of quantum wells and of barrier layers.

In FIGS. 1 and 2, each light-emitting diode LED has the shape of a cylinder with a circular base of axis A. However, each light-emitting diode LED may have the shape of a cylinder of axis A with a polygonal base, for example, square, rectangular, or hexagonal. Preferably, each light-emitting diode LED has the shape of a cylinder with a hexagonal base.

Call height H of light-emitting diode LED the sum of the height h1 of lower semiconductor portion 18, of the height h2 of active area 20, of the height h3 of upper semiconductor portion 22, of the thickness of electrode layer 26, and of the thickness of coating 28.

According to an embodiment, light-emitting diodes LED are arranged to form a photonic crystal. Twelve light-emitting diodes LED are shown as an example in FIG. 2. In practice, array 15 may comprise from 7 to 100,000 light-emitting diodes LED.

The light-emitting diodes LED of array 15 are arranged in rows and in columns (3 rows and 4 columns being shown as an example in FIG. 2). The pitch ‘a’ of array 15 is the distance between the axis of a light-emitting diode LED and the axis of a close light-emitting diode LED, in the same row or in an adjacent row. Pitch a is substantially constant. More particularly, pitch a of the array is selected so that array 15 forms a photonic crystal. The formed photonic crystal is for example, a 2D photonic crystal.

The properties of the photonic crystal formed by array 15 are advantageously selected so that array 15 of light-emitting diodes forms a resonant cavity in the plane perpendicular to axis A and a resonant cavity along axis A, particularly to obtain a coupling and increase the selection effect. This enables the intensity of the radiation emitted by the assembly of light-emitting diodes LED of array 15 through emission surface 30 to be amplified for certain wavelengths with respect to an assembly of light-emitting diodes LED which would not form a photonic crystal.

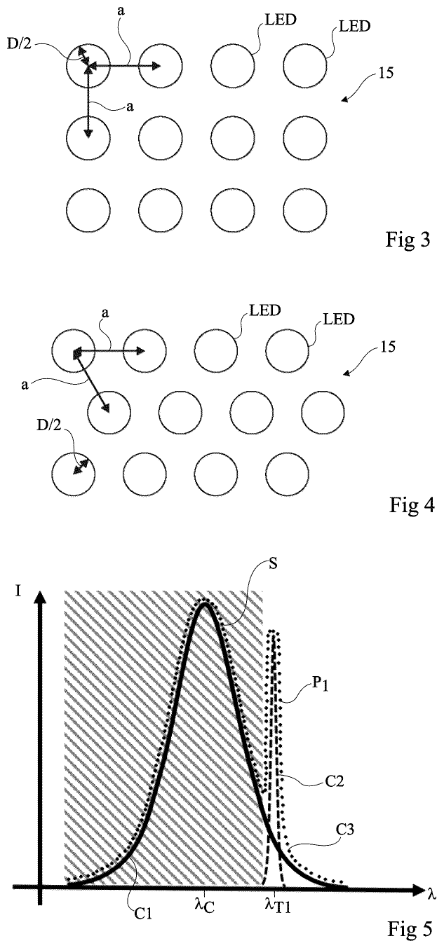

FIGS. 3 and 4 schematically show examples of layouts of the light-emitting diodes LED of array 15. In particular, FIG. 3 illustrates a so-called square lattice layout and FIG. 4 illustrates a so-called hexagonal lattice layout.

FIGS. 3 and 4 each show three rows of four light-emitting diodes LED. In the layout illustrated in FIG. 3, a light-emitting diode LED is located at each intersection of a row and of a column, the rows being perpendicular to the columns. In the layout illustrated in FIG. 4, the diodes on a row are shifted by half of pitch a with respect to the light-emitting diodes on the previous row and the next row.

In the embodiments illustrated in FIGS. 3 and 4, each light-emitting diode LED has a circular cross-section of diameter D in a plane parallel to surface 16. In the case of a hexagonal lattice layout or a square lattice layout, diameter D may be in the range from 0.05 μm to 2 μm. Pitch a may be in the range from 0.1 μm to 4 μm.

Further, according to an embodiment, the height H of light-emitting diode LED is selected so that each light-emitting diode LED forms a resonant cavity along axis A at the desired central wavelength λ of the radiation emitted by optoelectronic device 10. According to an embodiment height H is selected to be substantially proportional to k*(λ/2)*neff, neff being the effective refraction index of the light-emitting diode in the considered optical mode, and k being a positive integer. The effective refraction index is for example defined in work “Semiconductor Optoelectronic Devices: Introduction to Physics and Simulation” of Joachim Piprek.

In the case where the light-emitting diodes are distributed in groups of light-emitting diodes emitting at different central wavelengths, height H may however be the same for all light-emitting diodes. It may then be determined from the theoretical heights which would enable to obtain resonant cavities for the light-emitting diodes of each group, and is for example equal to the average of the theoretical heights.

According to an embodiment, the properties of the photonic crystal, formed by the array 15 of light-emitting diodes LED, are selected to increase the light intensity emitted by array 15 of light-emitting diodes LED at at least a target wavelength. According to an embodiment, the active area 20 of each light-emitting diode LED has an emission spectrum having a maximum at a wavelength different from the target wavelength. However, the emission spectrum of active area 20 covers the target wavelength, that is, the energy of the emission spectrum of active area 20 at the target wavelength is not null.

FIG. 5 schematically shows, according to wavelength λ, a curve C1 of the variation (in full line) of the light intensity I emitted by the active areas 20 of light-emitting diodes LED considered separately, a curve C2 of the variation (in dashed lines) of the amplification factor due to the coupling with the photonic crystal, and a curve C3 of the variation (in dotted lines) of the light intensity emitted by array 15 of light-emitting diodes. Curve C1 has a general “bell” shape and has a top at a central wavelength λ_{C}. Curve C2 corresponds to a narrow resonance peak centered on a target wavelength λ_{T1}. Curve C3 comprises a top S at central wavelength λ_{C} and a peak P₁ at target wavelength λ_{T1}. In particular, the full width at half-maximum of curve C3 for top S may be greater than the full width at half-maximum of curve C3 for peak P₁, for example, by a factor 2, in particular by a factor varying from 8 to 15, for example, equal to 10.

According to an embodiment, the obtaining of optoelectronic device 10 emitting a narrow-spectrum light radiation at target wavelength λ_{T1} may be obtained by filtering the radiation emitted by array 15 of light-emitting diodes LED to block wavelengths smaller than target wavelength λ_{T1}. This may be obtained by providing an optical filter in coating 28. In FIG. 5, the blocked portion of the spectrum of the radiation emitted by array 15 of light-emitting diodes is hatched. The spectrum of the radiation emitted by the emission surface 30 of optoelectronic device 10 then mainly comprises peak P₁.

This advantageously enables to form an active area 20 emitting a radiation of maximum intensity at a central wavelength λc different from target wavelength λ_{T1}. This further advantageously enables to be able to use an active area 20 emitting a radiation having its emission band at half-maximum greater than that of the target radiation. This further advantageously enables to ease the manufacturing of active area 20. Indeed, as an example, when active area 20 comprises an InGaN layer, the central wavelength of the emitted radiation increases with the proportion of indium. However, to obtain an emission wavelength corresponding to red, a proportion of indium greater than 16% should be obtained, which translates as a drop in the quantum efficiency of the active area. The fact of using an active area 20 emitting a radiation of maximum intensity at a central wavelength λc smaller than target wavelength λ_{T1} enables to use an active area 20 with an improved quantum efficiency. This further enables to obtain a radiation at target wavelength λ_{T1} by using an active area 20, emitting a radiation of maximum intensity at central wavelength λc, which is easier to manufacture, without having to use photoluminescent materials. Further, the height h1 of lower semiconductor portion 18 and the height h2 of upper semiconductor portion 22 are advantageously determined so that the light intensity of the peak at target wavelength λ_{T1} is maximum.

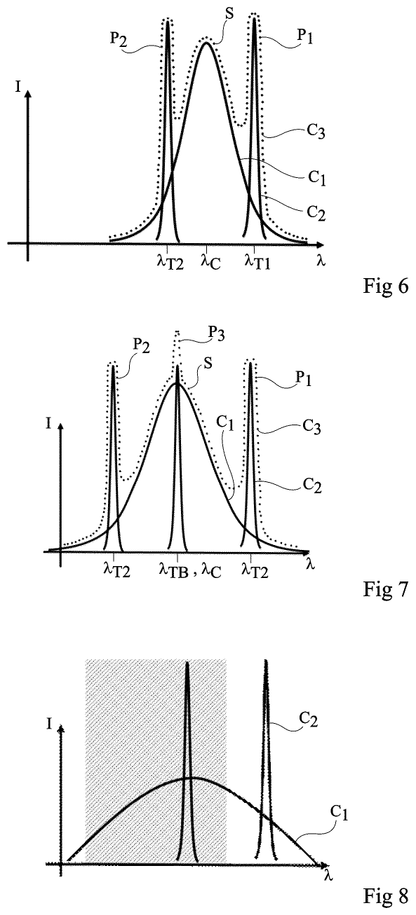

FIG. 6 is a drawing similar to FIG. 5, with the difference that the curve C2 of variation of the amplification factor due to the photonic crystal comprises two narrow resonance peaks respectively centered on targets wavelengths λ_{T1} and λ_{T2}. Curve C3 then comprises top S at central wavelength λ_{C}, peak P₁ at target wavelength λ_{T1}, and a peak P₂ at a target wavelength λ_{T2}.

FIG. 7 is a drawing similar to FIG. 5, with the difference that the curve C2 of variation of the amplification factor due to the photonic crystal comprises three narrow resonance peaks respectively centered on targets wavelengths λ_{T1}, λ_{T2}, and λ_{T3}. Curve C3 comprises top S at central wavelength λ_{C}, peak P₁ at target wavelength λ_{T1}, peak P₂ at target wavelength λ_{T2}, and a peak P₃ at target wavelength λ_{T3}, shown in FIG. 7 as being substantially equal to central wavelength λ_{C}.

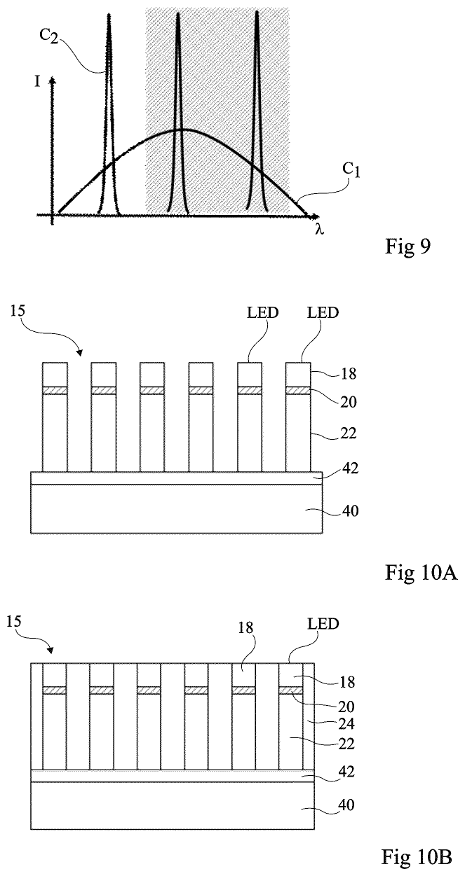

FIGS. 8 and 9 illustrate the principle of filtering of the radiation emitted by array 15 of light-emitting diodes for the configurations respectively with two resonance peaks and with three resonance peaks. As previously described in relation with FIG. 5, the obtaining of an optoelectronic device emitting a narrow-spectrum light radiation centered on target wavelength λ_{T1} may be obtained by blocking the unwanted portion of the emission spectrum of the light-emitting diodes. As an example, in FIGS. 8 and 9, the blocked portion of the spectrum of the radiation emitted by array 15 of light-emitting diodes is hatched and only one of the resonance peaks is kept.

The filtering of the radiation emitted by the array of light-emitting diodes may be performed by any means. According to an embodiment, the filtering is obtained by covering the light-emitting diodes with a layer of a colored material. According to another embodiment, the filtering is obtained by covering the light-emitting diodes with an interference filter.

According to an embodiment, in an emission configuration comprising at least two resonance peaks, the light-emitting diodes of the array of light-emitting diodes may be distributed into first and second groups of light-emitting diodes. A first filtering is implemented for the light-emitting diodes of the first group to only keep the first resonance peak and a second filtering is implemented for the light-emitting diodes of the second group to only keep the second resonance peak. An optoelectronic device configured for the emission of a first radiation at a first target wavelength and of a second radiation at a second target wavelength can thus be obtained while the active areas of the light-emitting diodes and the arrays of light-emitting diodes of the first and second groups have the same structure.

According to an embodiment, in an emission configuration comprising at least three resonance peaks, the light-emitting diodes may be distributed into first, second, and third groups of light-emitting diodes. A first filtering is implemented for the light-emitting diodes of the first group to only keep the first resonance peak. A second filtering is implemented for the light-emitting diodes of the second group to only keep the second resonance peak. A third filtering is implemented for the light-emitting diodes of the third group to only keep the third resonance peak. An optoelectronic device configured for the emission of a first radiation at a first target wavelength, of a second radiation at a second target wavelength, and of a third radiation at a third target wavelength can thus be obtained while the active areas of the light-emitting diodes and the arrays of light-emitting diodes of the first, second, and third groups have the same structure. This particularly enables to form display sub-pixels for a display pixel of a color image display screen.

According to an embodiment, the radiation after filtering of the first group of light-emitting diodes corresponds to blue light, that is, a radiation having a wavelength in the range from 430 nm to 480 nm. According to an embodiment, the radiation after filtering of the second group of light-emitting diodes corresponds to green light, that is, to a radiation having a wavelength in the range from 510 nm to 570 nm. According to an embodiment, the radiation after filtering of the third group of light-emitting diodes corresponds to red light, that is, a radiation having a wavelength in the range from 600 nm to 720 nm.

Advantageously, active areas 20 having the same structure and the same composition may be used to manufacture optoelectronic devices capable of emitting narrow-spectrum radiations at different target wavelengths. This enables to do away, on design of a new optoelectronic device, with the designing of a new structure for the active areas, with all the industrial development issues that this implies, and thus to simplify the method of designing a new optoelectronic device. Indeed, all the light-emitting diodes may be formed with the same structure, so that the initial steps of the manufacturing method at least until the manufacturing of the light-emitting diodes may be common for the manufacturing of different optoelectronic devices.

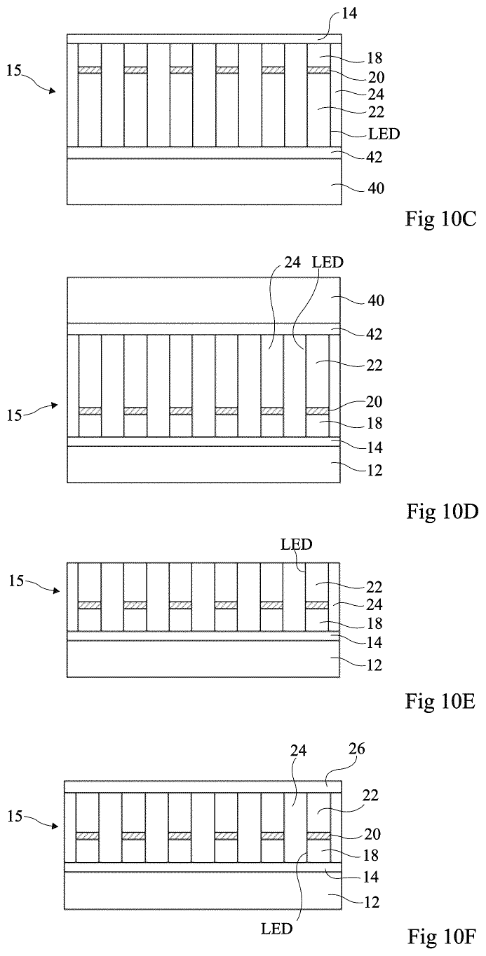

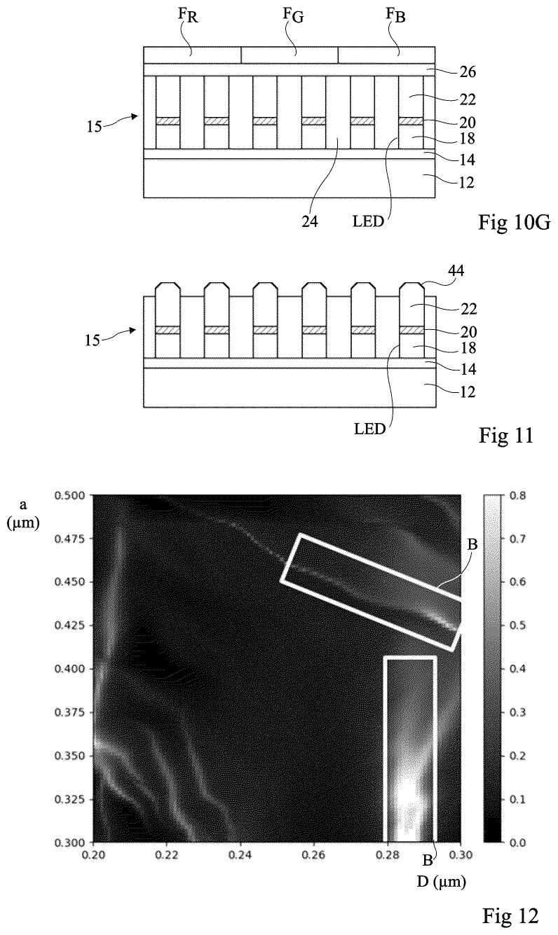

FIGS. 10A to 10G are partial simplified cross-section views of the structures obtained at successive steps of another embodiment of a method of manufacturing the optoelectronic device 10 shown in FIG. 1.

FIG. 10A illustrates the structure obtained after the forming steps described hereafter.

A seed layer 42 is formed on a substrate 40. Light-emitting diodes LED are then formed from seed layer 42. More particularly, light-emitting diodes LED are formed in such a way that upper semiconductor portions 22 are in contact with seed layer 42. Seed layer 42 is made of a material which favors the growth of upper semiconductor portions 22. For each light-emitting diode LED, active area 20 is formed on upper semiconductor portion 22 and lower semiconductor portion 18 is formed on active layer 20.

Further, light-emitting diodes LED are located to form array 15, that is, to form rows and columns with the desired pitch of array 15. Only one row is partially shown in FIGS. 10A to 10G.

A mask, not shown, may be formed before the forming of the light-emitting diodes on seed layer 42 to only expose the portions of seed layer 42 at the locations where the light-emitting diodes will be located. As a variant, seed layer 42 may be etched, before the forming of the light-emitting diodes, to form pads located at the locations where the light-emitting diodes will be formed.

The method of growing light-emitting diodes LED may be a method or a combination of methods such as chemical vapor deposition (CVD) or metal-organic chemical vapor deposition (MOCVD), also known as metal-organic vapor phase epitaxy (MOVPE). However, methods such as molecular-beam epitaxy (MBE), gas-source MBE (GSMBE), metal-organic MBE (MOMBE), plasma-assisted MBE (PAMBE), atomic layer epitaxy (ALE), or hydride vapor phase epitaxy (HVPE) may be used. However, electrochemical processes may be used, for example, chemical bath deposition (CBD), hydrothermal processes, liquid aerosol pyrolysis, or electrodeposition.

The conditions of growth of light-emitting diodes LED are such that all the light-emitting diodes of array 15 substantially form at the same speed. Thus, the heights of lower and upper semiconductor portions 18 and 22 and the height of active area 20 are substantially identical for all the light-emitting diodes of array 15.

According to an embodiment, the height of upper semiconductor portion 22 is greater than the desired height h3. Indeed, it may be difficult to accurately control the height of upper semiconductor region 22, particularly due to the beginning of the growth of upper semiconductor region 22 from seed layer 42. Further, the forming of the semiconductor directly on seed layer 42 may cause crystal defects in the semiconductor material just above seed layer 42. It may thus be desired to remove a portion of the upper semiconductor portion 22 to obtain a constant height before the forming of active area 20.

FIG. 10B illustrates the structure obtained after the forming of layer 24 of the filling material, for example, an electrically-insulating material, for example, silicon oxide. Layer 24 is for example formed by depositing a layer of a filling material on the structure shown in FIG. 10A, the layer having a thickness greater than the height of light-emitting diodes LED. The layer of filling material is then partially removed to be planarized to expose the upper surfaces of lower semiconductor portions 18. The upper surface of layer 24 is then substantially coplanar with the upper surface of each lower semiconductor portion 18. As a variant, the method may comprise an etch step during which lower semiconductor portions 18 are partially etched.

The filling material is selected so that the photonic crystal formed by array 15 has the desired properties, that is, it selectively improves, in terms of wavelength, the intensity of the radiation emitted by light-emitting diodes LED.

FIG. 10C illustrates the structure obtained after the deposition of electrode layer 14 on the structure obtained at the previous step.

FIG. 10D illustrates the structure obtained after the bonding to support 12 of layer 14, for example, by metal-to-metal bonding, by thermocompression, or by soldering with the use of eutectics on the side of support 12.

FIG. 10E illustrates the structure obtained after the removal of substrate 40 and of seed layer 42. Further, layer 24 and upper semiconductor portions 22 are etched so that the height of each upper semiconductor portion 22 has the desired value h3. This step advantageously enables to exactly control the height of the light-emitting diodes and to remove the portions of upper semiconductor portions 22 which may have crystal defects.

FIG. 10F illustrates the structure obtained after the deposition of electrode layer 26.

FIG. 10G illustrates the structure obtained after the forming of at least one optical filter on all or part of the structure shown in FIG. 10E. As an example, in a configuration with three resonance peaks such as previously described, first, second, and third optical filters F_{R}, F_{G}, F_{B}, respectively placed on first, second, and third groups of light-emitting diodes LED, have been shown.

FIG. 11 illustrates a variant of the method of manufacturing the optoelectronic device shown in FIG. 1 where a step of partial etching of the free end of each upper semiconductor portion 22 of light-emitting diodes LED is implemented before the forming of electrode layer 26. The step of partial etching may comprise the forming of inclined sides 44 at the free end of upper semiconductor portions 22. This enables to slightly modify the properties of the photonic crystal. This thus enables to more finely modify the position of the resonance peaks of the amplification due to the photonic crystal.

Simulations and tests have been carried out. For the simulations and for the tests, for each light-emitting diode LED, lower semiconductor portion 18 was made of P-type doped GaN. Upper semiconductor portion 22 was made of N-type doped GaN. The refraction index of lower and upper semiconductor portions 18 and 22 was in the range from 2.4 to 2.5. Active area 20 would correspond to an InGaN layer. The height h2 of active area 20 was equal to 40 nm. Electrode layer 14 was made of aluminum. Insulating layer 24 was made of a BCB polymer. The refraction index of insulating layer 24 was in the range from 1.45 to 1.56. For the simulations, a specular reflection on surface 16 has been considered. The height of lower and upper semiconductor portions 18 and 22 is not a determining parameter since it does not substantially modify the position of the resonance peaks, even if it has an impact on the intensity of the resonance peaks.

FIGS. 12, 13, and 14 are grayscale maps of the light intensity of the radiation emitted in a first direction inclined by 5 degrees with respect to a direction orthogonal to emission surface 30 respectively at a first, second, and third wavelength of array 15 of light-emitting diodes LED according to the pitch ‘a’ of the photonic crystal and to the diameter ‘D’ of each light-emitting diode. For the simulations, the first wavelength was 450 nm (blue), the second wavelength was 530 nm (green), and the third wavelength was 630 nm (red).

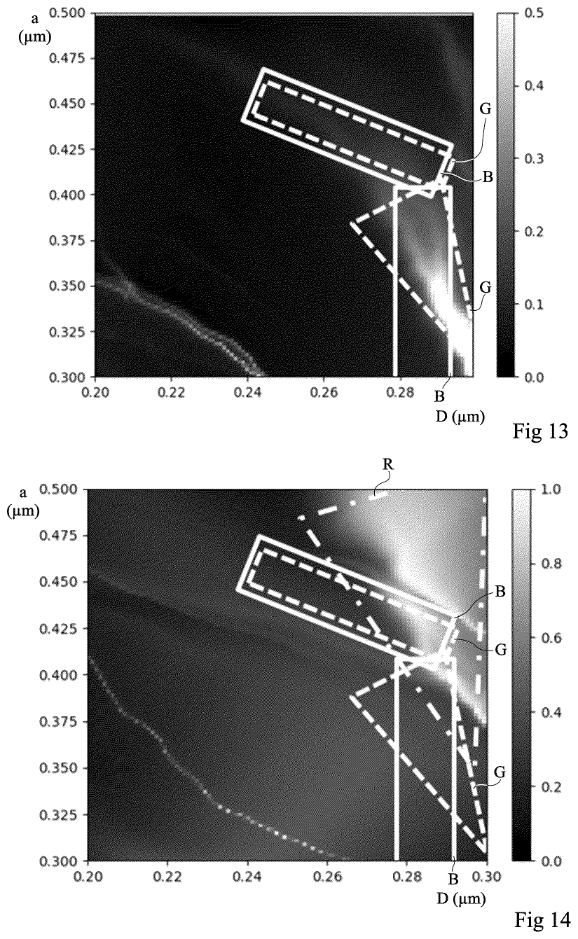

Each of the grayscale maps comprises lighter areas which correspond to resonance peaks. Such areas with resonance peaks are schematically indicated by contours B in full line in FIG. 12, by contours G in dotted lines in FIG. 13, and by contours R in stripe-dot lines in FIG. 14.

This thus means, as an example, that by selecting the pitch ‘a’ of the photonic crystal and the diameter ‘D’ of the light-emitting diodes to be located in one of the regions delimited by contours B in FIG. 12, the emission spectrum of array 15 of light-emitting diodes LED, obtained with no filtering, has at least one resonance peak at the 450-nm wavelength.

In FIG. 13, the contours B of FIG. 12 have been superposed to contours G. This thus means, as an example, that by selecting the pitch ‘a’ of the photonic crystal and the diameter ‘D’ of the light-emitting diodes to be located in one of the regions delimited both by contours B and G in FIG. 13, the emission spectrum of array 15 of light-emitting diodes LED, obtained with no filtering, has at least one resonance peak at the 450-nm wavelength and one resonance peak at the 530-nm wavelength.

In FIG. 14, the contours B of FIG. 12 and the contours G of FIG. 13 have been superposed to contours R. This thus means, as an example, that by the selection of the pitch ‘a’ of the photonic crystal and the diameter ‘D’ of the light-emitting diodes in order to be in one of the regions delimited both by contours B, G, and R in FIG. 14, the emission spectrum of array 15 of light-emitting diodes LED, obtained with no filtering, has at least one resonance peak at the 450-nm wavelength, a resonance peak at the 530-nm wavelength, and a resonance peak at the 630-nm wavelength.

It should be noted that an optimization may be performed by varying heights h1 and h3.

For the tests, the light-emitting diodes had a hexagonal base. Approximately, it has been considered that the simulations performed for light-emitting diodes with a circular base with a given radius are equivalent to simulations for which the light-emitting diodes would have a hexagonal base, with a circle circumscribed within the hexagonal cross-section having a radius equal to 1.1 time the given radius. Lower and upper semiconductor portions 18 and 22 and the active layers 20 of all the photodiodes have been simultaneously formed by MOCVD.

A first test has been performed with the following parameters: height H equal to approximately 1 μm, pitch ‘a’ of the photonic crystal equal to 400 nm, and diameter of the circle circumscribed within the hexagonal base of the light-emitting diodes of about 270 nm+/−25 nm. Considering a corrected diameter of about 297 nm on the simulation of FIG. 14, a resonance is expected at the 630-nm wavelength.

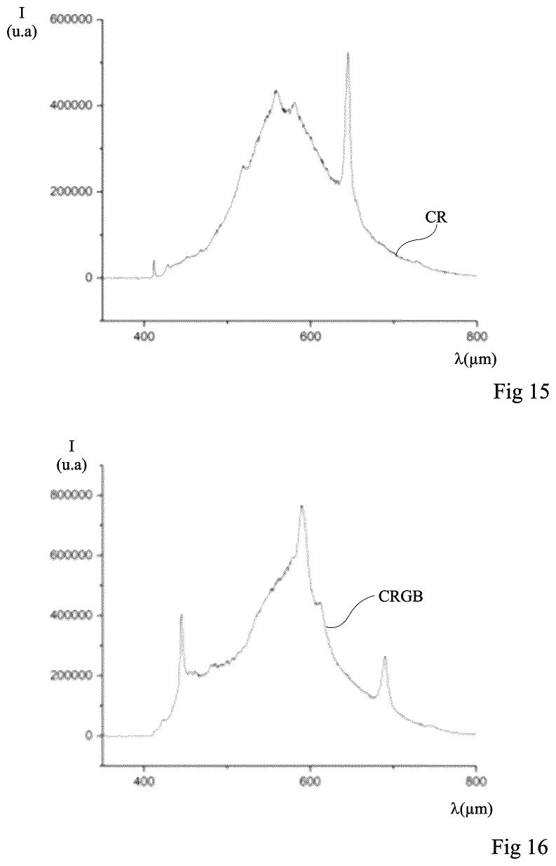

FIG. 15 shows a curve of the variation CR of the light intensity I, in arbitrary units, of array 15 of light-emitting diodes according to wavelength λ for the first test. An intensity peak is effectively obtained for a wavelength equal to approximately 644 nm.

A second test has been performed with the same base dimensions as the first test, with epitaxial growth conditions for the forming of the active areas (20) modified so as to lower slightly the global average diameter of each light-emitting diode to enter the R, G and B contours on the simulation of FIG. 14. With respect to the first test, modified parameters were the thickness of the quantum barrier of the active area that was increased, the In/III input flow that was increased and the temperature that was increased.

FIG. 16 shows a curve of the variation CRGB of the light intensity I, in arbitrary units, of array 15 of light-emitting diodes according to the wavelength for the second test. Three resonance peaks are effectively obtained at the 450-nm, 590-nm, and 700-nm wavelengths.

Various embodiments and variants have been described. Those skilled in the art will understand that certain features of these embodiments can be combined and other variants will readily occur to those skilled in the art. In particular, the previously-described coating 28 may comprise additional layers other than an optical filter or optical filters. In particular, coating 28 may comprise an antireflection layer, a protection layer, etc. Finally, the practical implementation of the described embodiments and variants is within the abilities of those skilled in the art based on the functional indications given hereabove.

1. Can optoelectronic device comprising an array of axial light-emitting diodes, the light-emitting diodes each comprising an active area configured to emit an electromagnetic radiation having an emission spectrum comprising a maximum at a first wavelength, the array forming a photonic crystal configured to form a resonance peak amplifying the intensity of said electromagnetic radiation at at least one second wavelength different from the first wavelength.

2. The device according to claim 1, further comprising a first optical filter covering at least one first portion of said array of light-emitting diodes, the first optical filter being configured to block said amplified radiation over a first wavelength range comprising the first wavelength and to give way to said amplified radiation over a second wavelength range comprising the second wavelength.

3. The device according to claim 1, wherein the emission spectrum of the active area has energy at the second wavelength.

4. The device according to claim 1, wherein the photonic crystal is configured to form a resonance peak amplifying the intensity of said electromagnetic radiation at at least one third wavelength different from the first and second wavelengths.

5. The device according to claim 4, wherein the emission spectrum of the active area has energy at the third wavelength.

6. The device according to claim 4, further comprising a second optical filter covering at least a second portion of said array of light-emitting diodes, the second optical filter being configured to block said amplified radiation over a third wavelength range comprising the first and second wavelengths and to give way to said amplified radiation over a fourth wavelength range comprising the third wavelength.

7. The device according to claim 4, wherein the photonic crystal is configured to form a resonance peak amplifying the intensity of said electromagnetic radiation at at least one fourth wavelength different from the first, second, and third wavelengths.

8. The device according to claim 7, wherein the emission spectrum of the active area has energy at the fourth wavelength.

9. The device according to claim 7, further comprising a third optical filter covering at least a third portion of said array of light-emitting diodes, the third optical filter being configured to block said amplified radiation over a fifth wavelength range comprising the first, second, and third wavelengths and to give way to said amplified radiation over a sixth wavelength range comprising the fourth wavelength.

10. The device according to claim 1, comprising a support having the light-emitting diodes resting thereon, each light-emitting diode comprising a stack of a first semiconductor portion resting on the support, of the active area in contact with the first semiconductor portion, and of a second semiconductor portion in contact with the active area.

11. The device according to claim 10, comprising a reflective layer between the support and the first semiconductor portions of the light-emitting diodes.

12. The device according to claim 11, wherein the reflective layer is made of metal.

13. The device according to claim 10, wherein the second semiconductor portions of the light-emitting diodes are covered with an electrically conductive layer at least partly transparent to the radiation emitted by the light-emitting diodes.

14. The device according to claim 1, wherein the light-emitting diodes are separated by an electrically-insulting material.

15. A method of manufacturing an optoelectronic device comprising an array of axial light-emitting diodes, the light-emitting diodes each comprising an active layer configured to emit an electromagnetic radiation having an emission spectrum comprising a maximum at a first wavelength, the array forming a photonic crystal configured to form a resonance peak amplifying the intensity of the electromagnetic radiation by the electromagnetic diodes at at least one second wavelength different from the first wavelength.

16. The method according to claim 15, wherein the forming of the light-emitting diodes of the array comprises the steps of:
forming second semiconductor portions on a substrate, the second semiconductor portions being separated from one another by the pitch of the array;
forming an active area on each second semiconductor portion; and
forming a first semiconductor portion on each active area.

17. The method according to claim 16, comprising a step of removing the substrate.
